(19) United States
(12) Patent Application Publication
(10) Pub. No.: US 2018/0239237 A1
(43) Pub. Date: Aug. 23, 2018

(54) PHOTOMASK AND MANUFACTURING METHOD THEREOF

(71) Applicant: Powerchip Technology Corporation, Hsinchu (TW)

(72) Inventor: Yi-Kai Lai, Taoyuan City (TW)

(73) Assignee: Powerchip Technology Corporation, Hsinchu (TW)

(21) Appl. No.: 15/588,722

(22) Filed: May 8, 2017

(30) Foreign Application Priority Data
Feb. 18, 2017 (TW) 106105460

(51) Int. Cl. G03F 1/36; C23C 16/44; G03F 1/26; G03F 1/60; G03F 1/80; G03F 1/78

(52) U.S. Cl. CPC G03F 1/36; C23C 16/44; G03F 1/78; G03F 1/60; G03F 1/80; G03F 1/26

(57) ABSTRACT

A photomask is provided. The photomask includes a substrate, a light-blocking main feature, and sub-resolution assist features (SRAFs). The light-blocking main feature is disposed on the substrate. The SRAFs are disposed on the substrate and located on at least one side of the light-blocking main feature. A space between two adjacent SRAFs of the SRAFs is equal to a width of each of the SRAFs, and a light transmittance of the SRAFs is 100%.

### CROSS-REFERENCE TO RELATED APPLICATION

This application claims the priority benefit of Taiwan application serial no. 106105460, filed on Feb. 18, 2017. The entirety of the above-mentioned patent application is hereby incorporated by reference herein and made a part of this specification.

### FIELD OF THE INVENTION

The invention relates to a photomask and a manufacturing method thereof. More particularly, the invention relates to a photomask having sub-resolution assist features (SRAFs) and a manufacturing method thereof.

### DESCRIPTION OF RELATED ART

In a semiconductor manufacturing process, the photolithography techniques are vital since processes including etching, doping, etc. cannot be achieved without performing the photolithography process. In the photolithography process, the resolution of exposure acts as an important indicator representing the quality of photolithography.

Features in an isolation region are more isolated, and problems of the insufficient depth of focus window (DOF window) may occur easily, which thus leads to a poor feature transfer capability. A photomask using sub-resolution assist features (SRAFs) is therefore developed by the industry to solve the problem of the insufficient DOF window.

A SRAF rule is required to be determined in order to prevent problems of interference imaging of SRAFs and optimize the DOF. Nevertheless, numerous parameters (e.g., the space between the SRAFs, the width of each of the SRAFs, the space between the SRAFs and the main light-blocking feature, etc.) have to be taken into consideration when determining the SRAF rule, a considerable amount of time is thereby required to perform simulation on the SRAFs, and a large number of testing features are also required to be designed. In addition, after a large number of testing features are formed on the photomask, much time is needed to collect and analyze data to determine the SRAF rule. Therefore, designing the photomask is rather time-consuming.

### SUMMARY OF THE INVENTION

The invention provides a photomask and a manufacturing method thereof, so as to effectively shorten the time required for designing a photomask.

In an embodiment of the invention, a photomask including a substrate, a light-blocking main feature, and sub-resolution assist features (SRAFs) is provided. The light-blocking main feature is disposed on the substrate. The SRAFs are disposed on the substrate and located on at least one side of the light-blocking main feature. A space between two adjacent SRAFs of the SRAFs is equal to a width of each of the SRAFs, and a light transmittance of the SRAFs is 100%.

According to an embodiment of the invention, in the photomask, a material of the substrate is, for example, quartz.

According to an embodiment of the invention, in the photomask, the light-blocking main feature may be a single-layered structure or a multi-layered structure.

According to an embodiment of the invention, in the photomask, when the light-blocking main feature is the multi-layered structure, the light-blocking main feature includes a first light-blocking feature and a second light-blocking feature. The second light-blocking feature is disposed on the first light-blocking feature.

According to an embodiment of the invention, in the photomask, a material of the first light-blocking feature is, for example, a phase shift material.

According to an embodiment of the invention, in the photomask, a material of the first light-blocking feature is, for example, metal silicide, metal fluoride, metal silicide oxide, metal silicide nitride, metal silicide oxynitride, metal silicide carbide oxide, metal silicide carbide nitride, metal silicide carbide oxynitride, an alloy thin film, a metal thin film, or a combination thereof.

According to an embodiment of the invention, in the photomask, a light transmittance of the first light-blocking feature is, for example, 4% to 20%.

According to an embodiment of the invention, in the photomask, a material of the second light-blocking feature is, for example, chromium.

According to an embodiment of the invention, in the photomask, a light transmittance of the second light-blocking feature is, for example, 0.

According to an embodiment of the invention, in the photomask, a material of the SRAFs is, for example, hybrid organic siloxane polymer (HOSP), methyl silsesquioxane (MSQ), or hydrogen silsesquioxane (HSQ).

In an embodiment of the invention, a manufacturing method of a photomask including following steps is provided. A light-blocking main feature is formed on a substrate. SRAFs are formed on the substrate. The SRAFs are located on at least one side of the light-blocking main feature. A space between two adjacent SRAFs of the SRAFs is equal to a width of each of the SRAFs, and a light transmittance of the SRAFs is 100%.

According to an embodiment of the invention, in the manufacturing method of the photomask, a manufacturing method of the light-blocking main feature includes following steps. A first light-blocking layer is formed on the substrate. A second light-blocking layer is formed on the first light-blocking layer. A first patterned photoresist layer is formed on the second light-blocking layer. The first light-blocking layer and the second light-blocking layer not covered by the first patterned photoresist layer are removed to form a second light-blocking feature and a first light-blocking feature. The first patterned photoresist layer is then removed.

According to an embodiment of the invention, in the manufacturing method of the photomask, the manufacturing method of the light-blocking main feature further includes following steps. A second patterned photoresist layer is formed. The second light-blocking feature is exposed by the second patterned photoresist layer. The second light-blocking feature exposed by the second patterned photoresist layer is removed. The second patterned photoresist layer is then removed.

According to an embodiment of the invention, in the manufacturing method of the photomask, the manufacturing method of the light-blocking main feature includes following steps. A light-blocking layer is formed on the substrate. A patterned photoresist layer is formed on the light-blocking layer. The light-blocking layer not covered by the patterned photoresist layer is removed to form the light-blocking main feature. The patterned photoresist layer is then removed.

According to an embodiment of the invention, in the manufacturing method of the photomask, a manufacturing method of the SRAFs includes following steps. A SRAF layer is formed on the substrate. A local irradiation process is performed on the SRAF layer to form the SRAFs in the SRAF layer. A development process is performed to remove the SRAF layer where no local irradiation process is performed.

According to an embodiment of the invention, in the manufacturing method of the photomask, the local irradiation process is, for example, an electron beam irradiation process.

According to an embodiment of the invention, in the manufacturing method of the photomask, a material of the SRAF layer may be, for example, HOSP, MSQ, or HSQ.

According to an embodiment of the invention, in the manufacturing method of the photomask, when the material of the SRAF layer is the HOSP, a developer used in the development process may be propyl acetate.

According to an embodiment of the invention, in the manufacturing method of the photomask, when the material of the SRAF layer is the MSQ, the developer used in the development process may be ethanol.

According to an embodiment of the invention, in the manufacturing method of the photomask, when the material of the SRAF layer is the HSQ, the developer used in the development process is, for example, tetramethylammonium hydroxide (TMAH).

In view of the foregoing, in the photomask and the manufacturing method thereof provided by the embodiments of the invention, the space between two adjacent SRAFs is equal to the width of each of the SRAFs, and the light transmittance of the SRAFs is 100%, such that zero-order light is not generated after a light ray passes through the SRAFs, and that the problem of interference imaging of the SRAFs can be prevented. Thereby, parameters that are required to be taken into consideration when determining the SRAF rule may be significantly decreased, and a simulation duration of the SRAFs and the time required for collecting and analyzing data are significantly reduced as well. The time required for designing the photomask may therefore be further shortened effectively.

To make the aforementioned and other features and advantages of the invention more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1G are cross-sectional views of a manufacturing process of a photomask according to an embodiment of the invention.

FIG. 2 is a top view of FIG. 1G.

FIG. 3 is a cross-sectional view of a photomask according to another embodiment of the invention.

FIG. 4 is a top view of FIG. 3.

FIG. 5A to FIG. 5C are cross-sectional views of a manufacturing process of a photomask according to another embodiment of the invention.

FIG. 6 is a top view of FIG. 5C.

### DESCRIPTION OF THE EMBODIMENTS

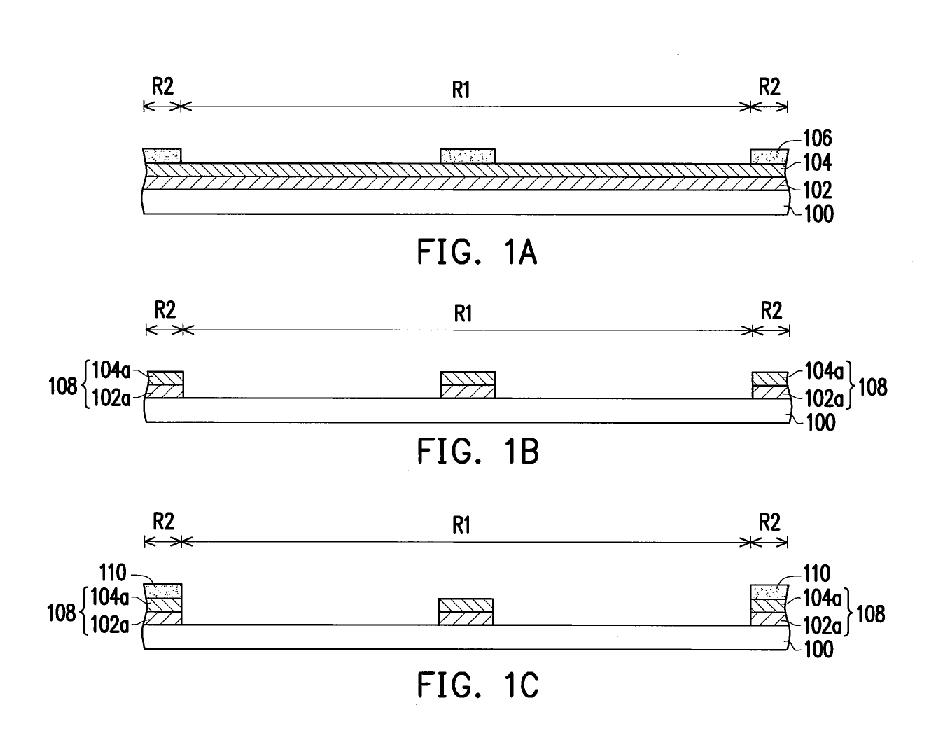

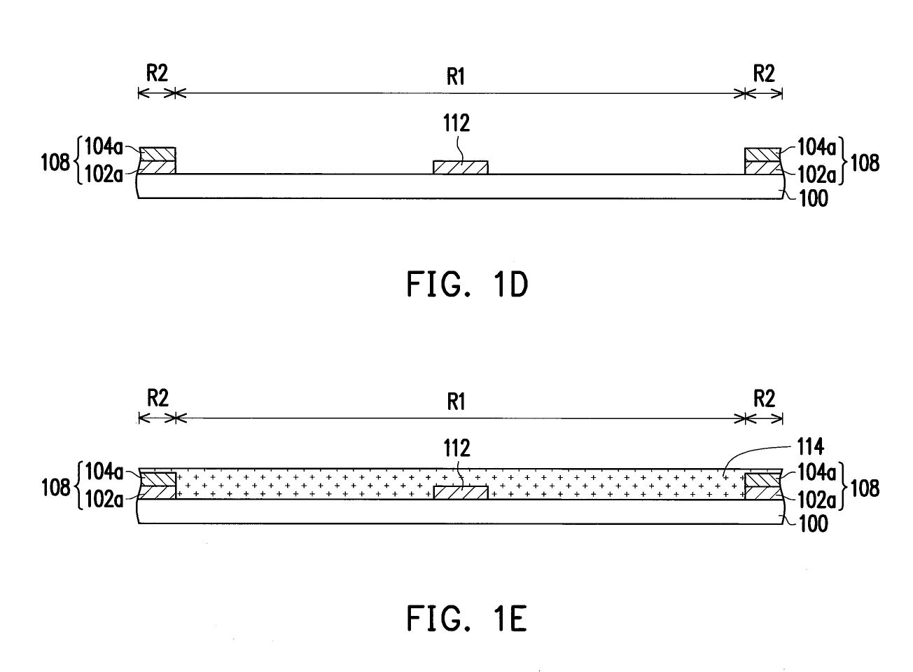

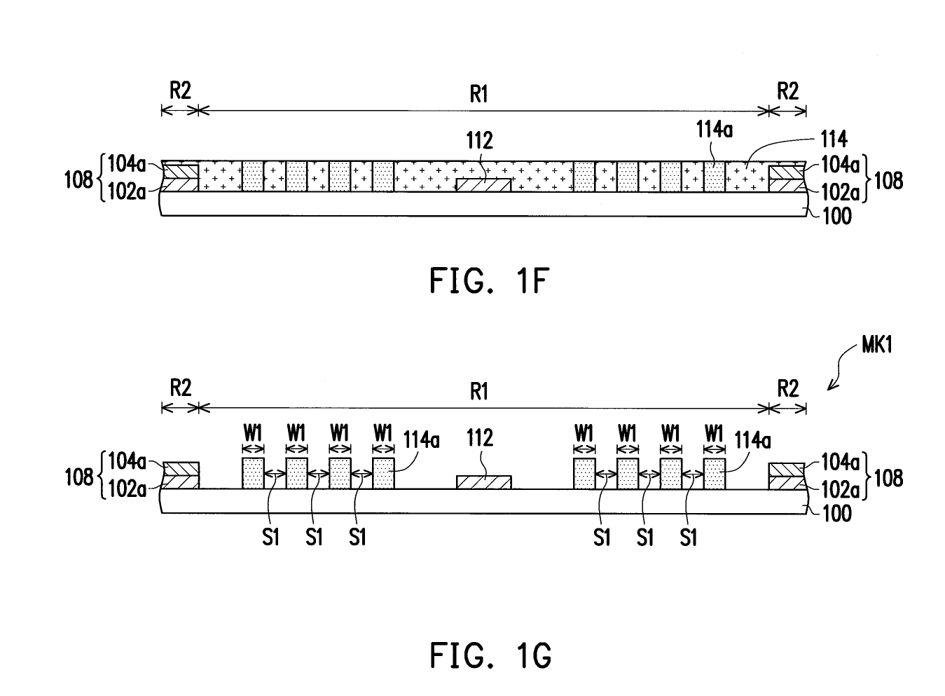

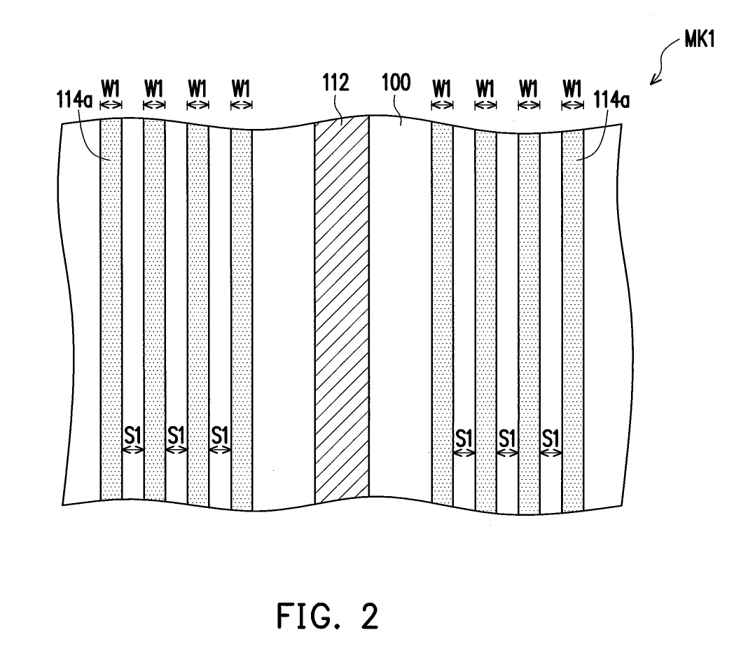

FIG. 1A to FIG. 1G are cross-sectional views of a manufacturing process of a photomask according to an embodiment of the invention. FIG. 2 is a top view of FIG. 1G. In FIG. 2, mark features in FIG. 1G are omitted in order to give a clearer illustration.

Referring to FIG. 1A, a light-blocking layer 102 is formed on a substrate 100. The substrate 100 may include a main feature region R1 and selectively include a mark feature region R2. The substrate 100 is, for example, a transparent substrate. A material of the substrate 100 is, for example, quartz.

A material of the light-blocking layer 102 is, for example, a phase shift material, such as metal silicide, metal fluoride, metal silicide oxide, metal silicide nitride, metal silicide oxynitride, metal silicide carbide oxide, metal silicide carbide nitride, metal silicide carbide oxynitride, an alloy thin film, a metal thin film, or a combination thereof. A light transmittance of the light-blocking layer 102 is, for example, 4% to 20%. In the embodiment, molybdenum silicide is exemplified as the material of the light-blocking layer 102, and a light transmittance of 6% is exemplified as the light transmittance of the light-blocking layer 102. A method of forming the light-blocking layer 102 is, for example, a physical vapor deposition method or a chemical vapor deposition method.

A light-blocking layer 104 is formed on the light-blocking layer 102. A material of the light-blocking layer 104 is, for example, an opaque material, such as chromium. A light transmittance of the light-blocking layer 104 is, for example, 0. A method of forming the light-blocking layer 104 is, for example, the physical vapor deposition method.

A patterned photoresist layer 106 is formed on the light-blocking layer 104. A material of the patterned photoresist layer 106 may be a positive photoresist material or a negative photoresist material. The patterned photoresist layer 106 is formed by, for example, the photolithography process.

Referring to FIG. 1B, the light-blocking layer 102 and the light-blocking layer 104 not covered by the patterned photoresist layer 106 are removed to form a light-blocking feature 102a and a light-blocking feature 104a. A method of removing the light-blocking layer 102 and the light-blocking layer 104 not covered by the patterned photoresist layer 106 is, for example, a dry etching method.

The light-blocking feature 104a and the light-blocking feature 102a in the mark feature region R2 may be configured to act as a mark feature 108. The mark feature 108 is, for example, an alignment mark or an overlay mark. The alignment mark may be configured to perform position alignment, and the overlay mark may be configured to measure overlay accuracy.

The patterned photoresist layer 106 is removed. A method of removing the patterned photoresist layer 106 is, for example, a dry stripping method or a wet stripping method.

Referring to FIG. 1C, a patterned photoresist layer 110 is formed. The light-blocking feature 104a in the main feature region R1 is exposed by the patterned photoresist layer 110. In addition, the light-blocking feature 104a in the mark feature region R2 may be covered by the light-blocking feature 104a. A material of the patterned photoresist layer 110 may be a positive photoresist material or a negative photoresist material. The patterned photoresist layer 110 is formed by, for example, the photolithography process.

Referring to FIG. 1D, the light-blocking feature 104a exposed by the patterned photoresist layer 110 is removed to form a light-blocking main feature 112 on the substrate 100. In the embodiment, the light-blocking main feature 112 is exemplified as a single-layered structure formed by the light-blocking feature 102a in the main feature region R1, but the invention is not limited thereto. In other embodiments, the light-blocking main feature 112 may also be a multi-layered structure.

The patterned photoresist layer 110 is removed. A method of removing the patterned photoresist layer 110 is, for example, the dry stripping method or the wet stripping method.

Referring to FIG. 1E, a SRAF layer 114 is formed on the substrate 100. The mark feature 108 and the light-blocking main feature 112 may be covered by the SRAF layer 114. A light transmittance of the SRAF layer 114 is 100%. A material of the SRAF layer 114 is, for example, HOSP, MSQ, or HSQ. A method of forming the SRAF layer 114 is, for example, a spin coating method.

Referring to FIG. 1F, a local irradiation process is performed on the SRAF layer 114 to form SRAFs 114a in the SRAF layer 114. The local irradiation process is, for example, an electron beam irradiation process. A bonding structure in the SRAF layer 114 where no local irradiation process is performed is, for example, a cage-like structure, while a bonding structure in the SRAFs 114a where the local irradiation process is performed is, for example, a network structure.

Referring to FIG. 1G, a development process is performed to remove the SRAF layer 114 where no local irradiation process is performed and to form SRAFs 114a on the substrate 100. The SRAFs 114a are located on at least one side of the light-blocking main feature 112. A space S1 between two adjacent SRAFs 114a is equal to a width W1 of each of the SRAFs 114a, and a light transmittance of the SRAFs 114a is 100%.

During the development process, the degree of crosslinking of the SRAFs 114a where the local irradiation process is performed is greater than that of the SRAF layer 114 where no local irradiation process is performed; as such, the SRAFs 114a with the greater degree of crosslinking are left after the development process is performed.

For instance, when the material of the SRAF layer 114 is HOSP, a developer used in the development process may be propyl acetate. When the material of the SRAF layer 114 is MSQ, the developer used in the development process may be ethanol. When the material of the SRAF layer 114 is HSQ, the developer used in the development process may be TMAH.

A structure of a photomask MK1 is described below with reference to FIG. 1G and FIG. 2.

Referring to FIG. 1G and FIG. 2, the photomask MK1 includes the substrate 100, the light-blocking main feature 112, and the SRAFs 114a. The substrate 100 may include the main feature region R1 and selectively may include the mark feature region R2. The light-blocking main feature 112 and the SRAFs 114a are located in the main feature region R1. The light-blocking main feature 112 is disposed on the substrate 100. The light-blocking main feature 112 is, for example, a feature in an isolation region. The SRAFs 114a are disposed on the substrate 100 and located on at least one side of the light-blocking main feature 112. The space S1 between two adjacent SRAFs 114a is equal to the width W1 of each of the SRAFs 114a, and the light transmittance of the SRAFs 114a is 100%. In addition, the photomask MK1 may further selectively include the mark feature 108 located in the mark feature region R2. The mark feature 108 includes the light-blocking feature 102a and the light-blocking feature 104a. The light-blocking feature 104a is disposed on the light-blocking feature 102a. In addition, in the embodiments, the materials and the characteristics of each of the elements of the photomask MK1 as well as the method of forming the elements and the way to arrange the elements are described above in details and thus will not be further elaborated.

According to the embodiments, it can be seen that in the photomask MK1 and the manufacturing method thereof, the space S1 between two adjacent SRAFs 114a is equal to the width W1 of each of the SRAFs 114a, and the light transmittance of the SRAFs 114a is 100%, such that zero-order light is not generated after a light ray passes the SRAFs 114a. As such, the problem of interference imaging of the SRAFs 114a can be prevented. Thereby, parameters that are required to be taken into consideration when determining a rule of the SRAFs 114a may be significantly decreased, and a simulation duration of the SRAFs 114a and the time required for collecting and analyzing data are significantly reduced. The time required for designing the photomask MK1 may therefore be further shortened effectively.

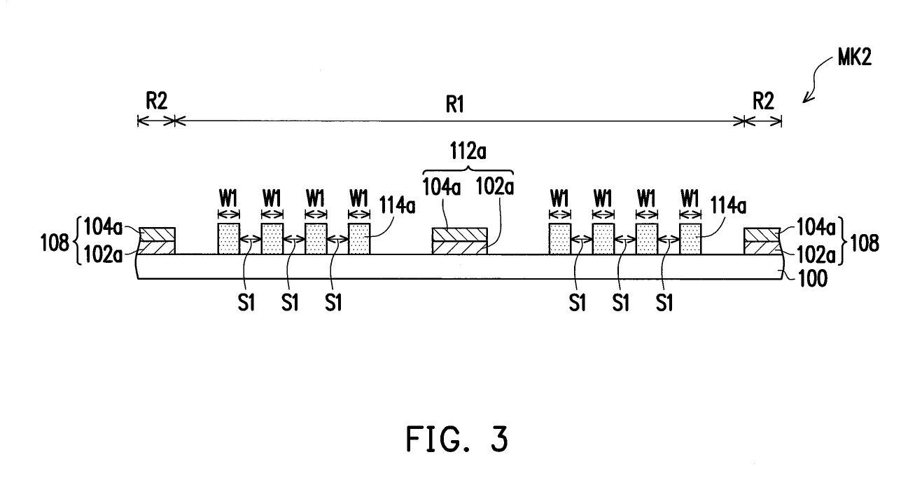

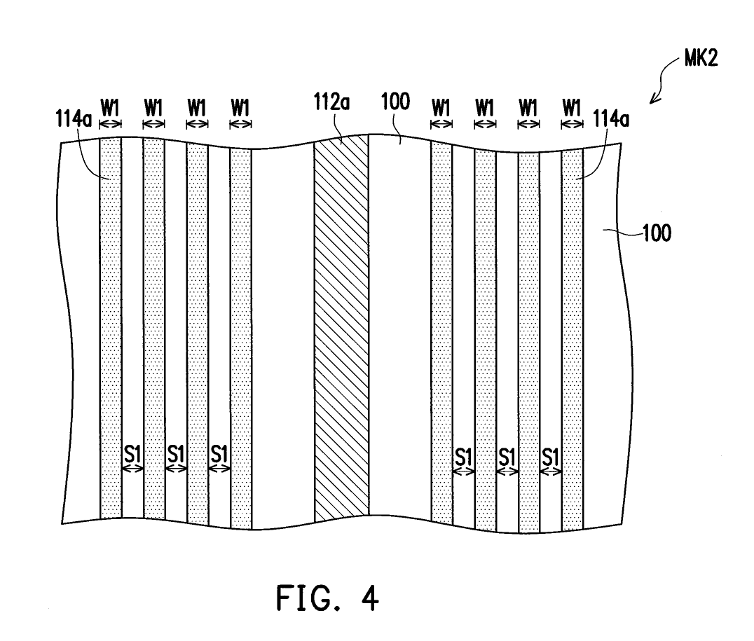

FIG. 3 is a cross-sectional view of a photomask according to another embodiment of the invention. FIG. 4 is a top view of FIG. 3. In FIG. 4, the mark features in FIG. 3 are omitted in order to give a clearer illustration.

Referring to FIG. 1G, FIG. 2, FIG. 3, and FIG. 4, the differences between a photomask MK2 in FIG. 3 and FIG. 4 and the photomask MK1 in FIG. 1G and FIG. 2 are described below. In the photomask MK2, a light-blocking main feature 112a is a multi-layered structure. The light-blocking main feature 112a includes the light-blocking feature 102a and the light-blocking feature 104a located in the main feature region R1. The light-blocking feature 104a is disposed on the light-blocking feature 102a. Besides, a difference between a method of forming the photomask MK2 and the method of forming the photomask MK1 is described below. Compared to the manufacturing method of the photomask MK1 illustrated in FIG. 1A to FIG. 1G, a step configured to remove the light-blocking feature 104a in the main feature region R1 illustrated in FIG. 1C and FIG. 1D is not performed in the manufacturing method of the photomask MK2. By contrast, effects of the photomask MK2 and the photomask MK1 are similar, and identical elements are indicated by the same reference numbers and will not be further elaborated.

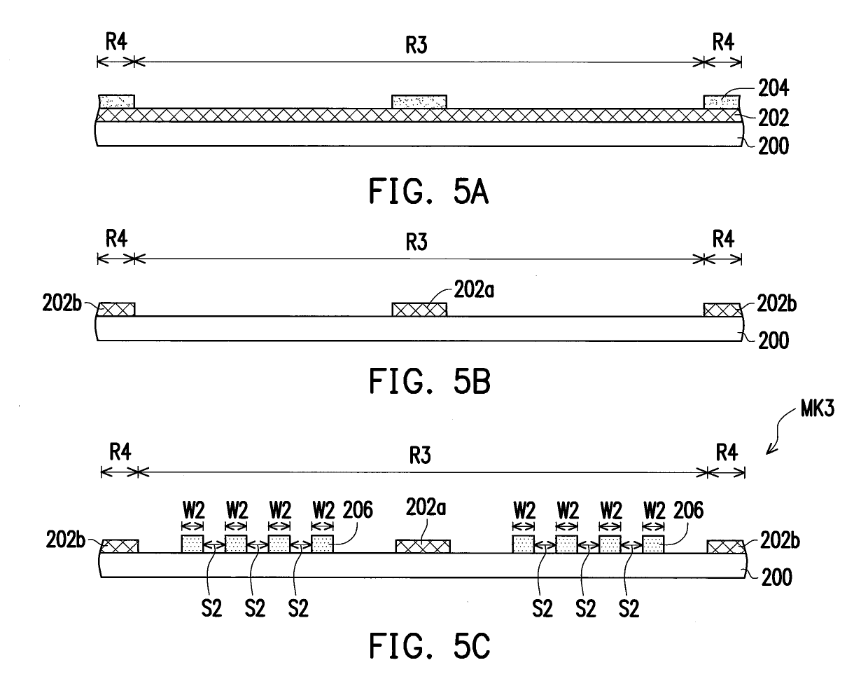

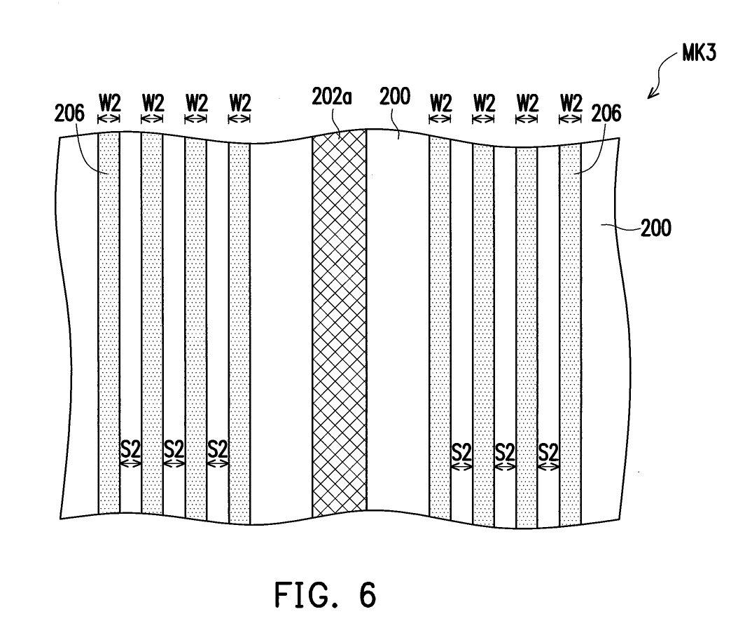

FIG. 5A to FIG. 5C are cross-sectional views of a manufacturing process of a photomask according to another embodiment of the invention. FIG. 6 is a top view of FIG. 5C. In FIG. 6, mark features in FIG. 5C are omitted in order to give a clearer illustration.

Referring to FIG. 5A, a light-blocking layer 202 is formed on a substrate 200. The substrate 200 may include a main feature region R3 and may selectively include a mark feature region R4. The substrate 200 is, for example, a transparent substrate. A material of the substrate 200 is, for example, quartz.

A material of the light-blocking layer 202 is, for example, a phase shift material or an opaque material. The phase shift material is, for example, metal silicide, metal fluoride, metal silicide oxide, metal silicide nitride, metal silicide oxynitride, metal silicide carbide oxide, metal silicide carbide nitride, metal silicide carbide oxynitride, an alloy thin film, a metal thin film, or a combination thereof. A light transmittance of the phase shift material is, for example, 4% to 20%. The opaque material is, for example, chromium. A light transmittance of the opaque material is, for example, 0. A method of forming the light-blocking layer 202 is, for example, the physical vapor deposition method or the chemical vapor deposition method.

A patterned photoresist layer 204 is formed on the light-blocking layer 202. A material of the patterned photoresist layer 204 may be a positive photoresist material or a negative photoresist material. The patterned photoresist layer 204 is formed by, for example, the photolithography process.

Referring to FIG. 5B, the light-blocking layer 202 not covered by the patterned photoresist layer 204 is removed. A light-blocking main feature 202a is formed on the substrate 200 in the main feature region R3, and a mark feature 202b may further be formed on the substrate 200 in the mark feature region R4. The mark feature 202b is, for example, the alignment mark or the overlay mark. In addition, a method of removing the light-blocking layer 202 not covered by the patterned photoresist layer 204 is, for example, the dry etching method.

In the embodiment, the light-blocking main feature 202a is exemplified as a single-layered structure, but the invention is not limited thereto. In other embodiments, the light-blocking main feature 202a may also be a multi-layered structure.

The patterned photoresist layer 204 is removed. A method of removing the patterned photoresist layer 204 is, for example, the dry stripping method or the wet stripping method.

Referring to FIG. 5C, SRAFs 206 are formed on the substrate 200. The SRAFs 206 are located on at least one side of the light-blocking main feature 202a. A space S2 between two adjacent SRAFs 206 is equal to a width W2 of each of the SRAFs 206, and a light transmittance of the SRAFs 206 is 100%. A material of the SRAFs 206 is, for example, HOSP, MSQ, or HSQ. A method of forming the SRAFs 206 may be referred to as the method of forming the SRAFS 114a illustrated in FIG. 1E to FIG. 1G, and thus the detailed description thereof is omitted.

A structure of a photomask MK3 is described below with reference to FIG. 5C and FIG. 6.

Referring to FIG. 5C and FIG. 6, the photomask MK3 includes the substrate 200, the light-blocking main feature 202a, and the SRAFs 206. The substrate 200 may include the main feature region R3 and may selectively include the mark feature region R4. The light-blocking main feature 202a and the SRAFs 206 are located in the main feature region R3. The light-blocking main feature 202a is disposed on the substrate 200. The light-blocking main feature 202a is, for example, a feature in the isolation region. The SRAFs 206 are disposed on the substrate 200 and located on at least one side of the light-blocking main feature 202a. The space S2 between two adjacent SRAFs 206 is equal to the width W2 of each of the SRAFs 206, and the light transmittance of the SRAFs 206 is 100%. In addition, the photomask MK3 may further selectively include the mark feature 202b. The mark feature 202b is disposed on the substrate 200 in the mark feature region R4. In addition, in the embodiments, the materials and the characteristics of each of the elements of the photomask MK3 as well as the method of forming the elements and the way to arrange the elements are described above in details and thus will not be further elaborated.

According to the embodiments, it can be seen that in the photomask MK3 and the manufacturing method thereof, the space S2 between two adjacent SRAFs 206 is equal to the width W2 of each of the SRAFs 206, and the light transmittance of the SRAFs 206 is 100%, such that zero-order light is not generated after a light ray passes the SRAFs 206. As such, the problem of interference imaging of the SRAFs 206 can be prevented. Thereby, parameters that are required to be taken into consideration when determining a rule of the SRAFs 206 may be significantly decreased, and a simulation duration of the SRAFs 206 and the time required for collecting and analyzing data are significantly reduced. The time required for designing the photomask MK3 may therefore be further shortened effectively.

To sum up, in the photomask and the manufacturing method thereof provided in the embodiments, the space between two adjacent SRAFs is equal to the width of each of the SRAFs, and the light transmittance of the SRAFs is 100%, such that the problem of interference imaging of the SRAFs can be prevented. As such, the time required for designing the photomask may be shortened effectively.

It will be apparent to those skilled in the art that various modifications and variations can be made to the disclosed embodiments without departing from the scope or spirit of the invention. In view of the foregoing, it is intended that the invention covers modifications and variations provided that they fall within the scope of the following claims and their equivalents.

What is claimed is:

1. A photomask, comprising:
a substrate;
a light-blocking main feature, disposed on the substrate; and
sub-resolution assist features (SRAFs), disposed on the substrate and located on at least one side of the light-blocking main feature, wherein a space between two adjacent SRAFs of the SRAFs is equal to a width of each of the SRAFs, and a light transmittance of the SRAFs is 100%.

2. The photomask as claimed in claim 1, wherein a material of the substrate comprises quartz.

3. The photomask as claimed in claim 1, wherein the light-blocking main feature is a single-layered structure or a multi-layered structure.

4. The photomask as claimed in claim 1, wherein when the light-blocking main feature is a multi-layered structure, the light-blocking main feature comprises:
a first light-blocking feature; and
a second light-blocking feature, disposed on the first light-blocking feature.

5. The photomask as claimed in claim 4, wherein a material of the first light-blocking feature comprises a phase shift material.

6. The photomask as claimed in claim 4, wherein a material of the first light-blocking feature comprises metal silicide, metal fluoride, metal silicide oxide, metal silicide nitride, metal silicide oxynitride, metal silicide carbide oxide, metal silicide carbide nitride, metal silicide carbide oxynitride, an alloy thin film, a metal thin film, or a combination thereof.

7. The photomask as claimed in claim 4, wherein a light transmittance of the first light-blocking feature is 4% to 20%.

8. The photomask as claimed in claim 4, wherein a material of the second light-blocking feature comprises chromium.

9. The photomask as claimed in claim 4, wherein a light transmittance of the second light-blocking feature is 0.

10. The photomask as claimed in claim 1, wherein a material of the SRAFs comprises hybrid organic siloxane polymer, methyl silsesquioxane, or hydrogen silsesquioxane.

11. A manufacturing method of a photomask, comprising:
forming a light-blocking main feature on a substrate; and
forming sub-resolution assist features (SRAFs) on the substrate, wherein the SRAFs are located on at least one side of the light-blocking main feature, a space between two adjacent SRAFs of the SRAFs is equal to a width of each of the SRAFs, and a light transmittance of the SRAFs is 100%.

12. The manufacturing method of the photomask as claimed in claim 11, wherein a manufacturing method of the light-blocking main feature comprises:
forming a first light-blocking layer on the substrate;
forming a second light-blocking layer on the first light-blocking layer;
forming a first patterned photoresist layer on the second light-blocking layer;
removing the first light-blocking layer and the second light-blocking layer not covered by the first patterned photoresist layer to form a second light-blocking feature and a first light-blocking feature; and
removing the first patterned photoresist layer.

13. The manufacturing method of the photomask as claimed in claim 12, wherein the manufacturing method of the light-blocking main feature further comprises:
forming a second patterned photoresist layer, wherein the second patterned photoresist layer exposes the second light-blocking feature;
removing the second light-blocking feature exposed by the second patterned photoresist layer; and
removing the second patterned photoresist layer.

14. The manufacturing method of the photomask as claimed in claim 11, wherein the manufacturing method of the light-blocking main feature comprises:
forming a light-blocking layer on the substrate;
forming a patterned photoresist layer on the light-blocking layer;
removing the light-blocking layer not covered by the patterned photoresist layer to form the light-blocking main feature; and
removing the patterned photoresist layer.

15. The manufacturing method of the photomask as claimed in claim 11, wherein a manufacturing method of the SRAFs comprises:
forming a SRAF layer on the substrate;
performing a local irradiation process on the SRAF layer to form the SRAFs in the SRAF layer; and
performing a development process to remove the SRAF layer where no local irradiation process is performed.

16. The manufacturing method of the photomask as claimed in claim 15, wherein the local irradiation process comprises an electron beam irradiation process.

17. The manufacturing method of the photomask as claimed in claim 15, wherein a material of the SRAF layer comprises hybrid organic siloxane polymer, methyl silsesquioxane, or hydrogen silsesquioxane.

18. The manufacturing method of the photomask as claimed in claim 17, wherein when the material of the SRAF layer is the hybrid organic siloxane polymer, a developer used in the development process is propyl acetate.

19. The manufacturing method of the photomask as claimed in claim 17, wherein when the material of the SRAF layer is the methyl silsesquioxane, the developer used in the development process is ethanol.

20. The manufacturing method of the photomask as claimed in claim 17, wherein when the material of the SRAF layer is the hydrogen silsesquioxane, the developer used in the development process is tetramethylammonium hydroxide.
